(19) United States
(12) Patent Application Publication
(10) Pub. No.: US 2013/0322030 A1
(43) Pub. Date: Dec. 5, 2013

(54) PRINTED CIRCUIT BOARD

(71) Applicant: HON HAI PRECISION INDUSTRY CO., LTD., New Taipei (TW)

(72) Inventors: CHIA-MING YEH, New Taipei (TW); CHUN-YUAN TIEN, New Taipei (TW); CHIH-HUNG WU, New Taipei (TW)

(73) Assignee: HON HAI PRECISION INDUSTRY CO., LTD., New Taipei (TW)

(21) Appl. No.: 13/899,613

(22) Filed: May 22, 2013

(30) Foreign Application Priority Data
Jun. 5, 2012 (TW) 101120075

(51) Int. Cl. H05K 1/18

(52) U.S. Cl. CPC H05K 1/181
USPC 361/748

(57) ABSTRACT

A printed circuit board includes a power supply, a plurality of loads, a copper sheet, and a plurality of metal sheets mounted onto the copper sheet. The copper sheet is electronically connected between the power supply and the loads. The power supply outputs a plurality of currents to the loads via a plurality of current traces passing through the copper sheet, the plurality of metal sheets are located along the plurality of current traces.

### BACKGROUND

1. Technical Field

The exemplary disclosure generally relates to printed circuit boards, and particularly to a printed circuit board having a high current transmission efficiency.

2. Description of Related Art

A large area copper sheet of a printed circuit board is usually connected between a power supply and a load to transmit current signals. Current transmission efficiency of the copper sheet is low because the copper sheet has an equivalent impedance which is electronically connected between the power supply and the load. A typical way to increase the current transmission efficiency is to regulate positions of the power supply and the load to shorten copper traces between power supply and the load. However, when dense copper traces are located between the power supply and the load, it is difficult to adjust the positions of the power supply and the load.

Therefore, there is room for improvement within the art.

### BRIEF DESCRIPTION OF THE DRAWINGS

Many aspects of the embodiments can be better understood with reference to the drawings. The components in the drawings are not necessarily drawn to scale, the emphasis instead being placed upon clearly illustrating the principles of the disclosure.

FIG. 1 shows a schematic view of an exemplary embodiment of a printed circuit board.

FIG. 2 shows a schematic view of an exemplary embodiment of a metal sheet of the printed circuit board shown in FIG. 1.

### DETAILED DESCRIPTION

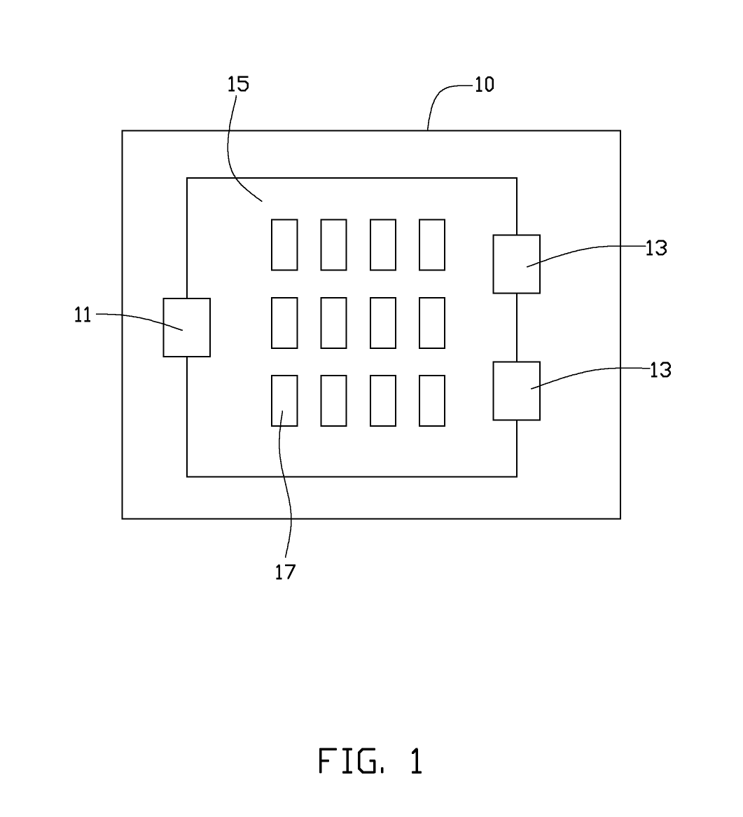

FIG. 1 shows a schematic view of an exemplary embodiment of a printed circuit board 10 including a power supply 11, a plurality of loads 13, a copper sheet 15, and a metal sheet 17. Each load 13 is electronically connected to the power supply 11 via the copper sheet 15. The power supply 11 outputs a plurality of currents flowing through the copper sheet 15 to the loads 13.

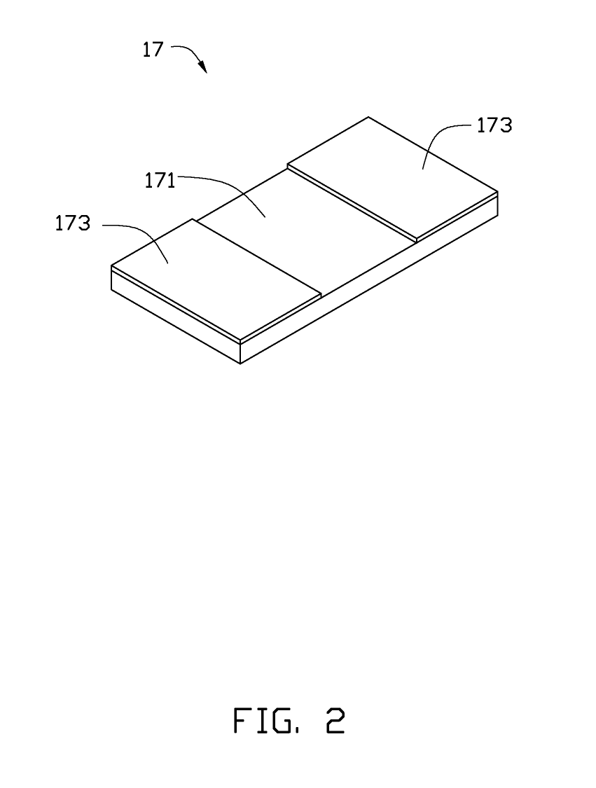

FIG. 2 shows a schematic view of an exemplary embodiment of the metal sheet 17 of the printed circuit board 10 shown in FIG. 1. The metal sheet 17 is mounted onto the copper sheet 15 using surface-mount technology (SMT), in one example. The metal sheet 17 includes a solder surface 171 and at least one solder pad 173 protruding from the solder surface 171. In the exemplary embodiment, the solder surface 171 has two solder pads 173 located at two opposite sides of the solder surface 171. The surface of the metal sheet 17, except the pads 173, is coated by insulating paint. The metal sheet 17 is soldered to the copper sheet 15 by the solder pads 173, such that the metal sheet 17 is electronically connected to the copper sheet 15 in parallel. In other words, an impedance of the metal sheet 17 is electronically connected to an impedance of the copper sheet 15 in parallel, therefore, a total impedance between the power supply 11 and the loads 13 is decreased, and the currents output to the loads 13 is increased correspondingly.

In one embodiment, the metal sheet 17 is a copper sheet. In other embodiment, the metal sheet 17 can be made of iron, silver, or other metal having a low characteristic impedance.

In the exemplary embodiment, a package of the metal sheet 17 is imperial 1210 (3.2×2.5 mm) or 2512 (6.4×3.2 mm)

In use, the power supply 11 outputs a plurality of currents the loads 13 via the copper sheet 15, therefore, a plurality of current traces are formed on the copper sheet 15. In the exemplary embodiment, the printed circuit board 10 includes a plurality of metal sheets 17. The metal sheets 17 are soldered on the copper sheet 15 and are arranged as an array, such as a matrix array, for example. The metal sheets 17 are preferred to be located on a portion of the copper sheet 15 where most current traces are passed through, such that the current transmission efficiency of the power supply 11 can be increased, and the heat generated by the copper sheet 15 can also be dissipated by the metal sheets 17. In other embodiment, the metal sheets 17 are located spaced along one of the current traces. The current traces passing through the copper sheet 15 can be obtained by executing a simulation software.

It is believed that the exemplary embodiments and their advantages will be understood from the foregoing description, and it will be apparent that various changes may be made thereto without departing from the spirit and scope of the disclosure or sacrificing all of its material advantages, the examples hereinbefore described merely being preferred or exemplary embodiments of the disclosure.

What is claimed is:

1. A printed circuit board, comprising:
a power supply;
a load;
a copper sheet electronically connected between the power supply and the load; and
a metal sheet mounted onto the copper sheet.

2. The printed circuit board of claim 1, wherein the metal sheet comprises a solder surface and at least one solder pad protruding from the solder surface, the metal sheet is soldered onto the copper sheet through the solder pad.

3. The printed circuit board of claim 2, wherein insulating paint coats the surface of the metal sheet except for the pads.

4. The printed circuit board of claim 1, wherein the metal sheet is made from the group consisting of copper, iron, and silver.

5. The printed circuit board of claim 1, wherein a package of the metal sheet is one of imperial 1210 and imperial 2512.

6. The printed circuit board of claim 1, further comprising a plurality of metal sheets, wherein the plurality of metal sheets are arranged as a matrix array.

7. A printed circuit board, comprising:
a power supply;
a plurality of loads;
a copper sheet electronically connected between the power supply and the loads;
a plurality of metal sheets mounted onto the copper sheet; and
wherein the power supply outputs a plurality of currents to the loads via the copper sheet, to form a plurality of current traces that pass through the copper sheet, the plurality of metal sheets are located along the plurality of current traces.

8. The printed circuit board of claim 7, wherein the metal sheets are located on a portion of the copper sheet where most current traces passed through.

9. The printed circuit board of claim 7, wherein the metal sheets are spacingly located along one of the current traces.

10. The printed circuit board of claim 7, wherein the metal sheet comprises a solder surface and at least one solder pad protruding from the solder surface, the metal sheet is soldered onto the copper sheet through the solder pad.

11. The printed circuit board of claim 10, wherein insulating paint coats the surface of the metal sheet except for the pads.

12. The printed circuit board of claim 7, wherein the metal sheet is made from the group consisting of copper, iron, and silver.

13. The printed circuit board of claim 7, wherein a package of the metal sheet is one of imperial 1210 and imperial 2512.

14. The printed circuit board of claim 7, further comprising a plurality of metal sheets, wherein the plurality of metal sheets are arranged as a matrix array.
